(19) United States
(12) Patent Application Publication
(10) Pub. No.: US 2015/0236223 A1
(43) Pub. Date: Aug. 20, 2015

(54) OPTOELECTRONIC COMPONENT

(71) Applicant: OSRAM Opto Semiconductors GmbH, Regensburg (DE)

(72) Inventor: Jürgen Moosburger, Lappersdorf (DE)

(21) Appl. No.: 14/428,667

(22) PCT Filed: Sep. 16, 2013
(86) PCT No.: PCT/EP2013/069165

§ 371 Date: Mar. 17, 2015

(30) Foreign Application Priority Data
Sep. 19, 2012 (DE) 10 2012 216 738.2

(51) Int. Cl. H01L 33/50; H01L 33/00; H01L 27/15; H01L 33/62

(52) U.S. Cl. CPC H01L 33/504; H01L 33/507; H01L 33/62; H01L 33/0095; H01L 27/156; H01L 2933/0041; H01L 2933/0066

(57) ABSTRACT

A method of producing an optoelectronic component includes providing at least one optoelectronic semiconductor chip; arranging a starting layer on the semiconductor chip, wherein the starting layer is present in the form of a film and includes a first phosphor; arranging a conversion element on the starting layer, wherein the conversion element includes a second phosphor; and curing the starting layer to form a connection layer.

### TECHNICAL FIELD

This disclosure relates to an optoelectronic component and to a method of producing such a component. The optoelectronic component comprises an optoelectronic semiconductor chip, and a first and a second phosphor.

### BACKGROUND

An optoelectronic component that emits warm-white light can be realized by a combination of an LED chip (Light Emitting Diode) emitting in the blue spectral range with two types of conversion means (“phosphors”). Use of a first phosphor which converts the blue light partially into red light, and a second phosphor which converts the blue light partially into yellow-green light, makes it possible to generate white light by additive mixing of the different spectral colors.

Such a component can be constructed such that a conversion element comprising the second (yellow-green-emitting) phosphor is adhesively bonded onto a semiconductor chip by a silicone adhesive, wherein the first (red-emitting) phosphor is contained in the silicone adhesive. As a result, a relatively small adhesive gap can be present between the conversion element and the semiconductor chip. In the context of production, first, the silicone adhesive can be dispensed as a drop onto the semiconductor chip, and then the conversion element can be pressed into the drop.

In that process sequence, however, it is difficult to set the quantity of the dispensed adhesive drop and thus the final height or thickness of the adhesive layer, connecting the conversion element to the semiconductor chip, with high accuracy. However, since the color locus of the light radiation emitted by the component depends on the thickness of this connection layer, the method described above is only slightly suitable to reliably produce the component with predefined color parameters.

It could therefore be helpful to provide a solution for an improved optoelectronic component.

### SUMMARY

I provide a method of producing an optoelectronic component including providing at least one optoelectronic semiconductor chip; arranging a starting layer on the semiconductor chip, wherein the starting layer is present in the form of a film and includes a first phosphor, and the starting layer is arranged on the semiconductor chip in a frozen state as a film lamina; arranging a ceramic conversion element on the starting layer, wherein the conversion element includes a second phosphor; and curing the starting layer to form a connection layer.

I further provide an optoelectronic component produced with the method of producing an optoelectronic component including providing at least one optoelectronic semiconductor chip; arranging a starting layer on the semiconductor chip, wherein the starting layer is present in the form of a film and includes a first phosphor, and the starting layer is arranged on the semiconductor chip in a frozen state as a film lamina; arranging a ceramic conversion element on the starting layer, wherein the conversion element includes a second phosphor; and curing the starting layer to form a connection layer, including a carrier; a plurality of optoelectronic semiconductor chips arranged on the carrier in a matrix like manner or in a line; a single connection layer in form of a lamina, including a first phosphor, the connection layer being arranged on the semiconductor chips; and a single ceramic conversion element in form of a lamina, including a second phosphor, the conversion element being arranged on the connection layer, wherein the connection layer covers the plurality of semiconductor chips and is in total formed by curing a film-type starting layer including the first phosphor, wherein the starting layer and the conversion element are placed on top of each other in a planar manner and the conversion element has larger lateral dimensions than the starting layer, and wherein the starting layer does not project laterally beyond an edge of the semiconductor chips of the matrix arrangement or of the line arrangement.

I yet further provide a method of producing an optoelectronic component including providing at least one optoelectronic semiconductor chip; arranging a starting layer on the semiconductor chip, wherein the starting layer is present in the form of a film and includes a first phosphor; arranging a conversion element on the starting layer, wherein the conversion element includes a second phosphor; and curing the starting layer to form a connection layer.

### BRIEF DESCRIPTION OF THE DRAWINGS

FIG. 1 shows a lateral illustration of an optoelectronic semiconductor chip arranged on a carrier, a silicone film and a ceramic conversion element prior to assembly.

FIG. 2 shows a plan view illustration of the component parts from FIG. 1.

FIG. 3 shows stamping-out of the silicone film from a larger film.

FIG. 4 shows a lateral illustration of an optoelectronic component constructed from the component parts from FIG. 1.

FIG. 5 shows a lateral illustration of a carrier with a plurality of semiconductor chips, a silicone film and a ceramic conversion element prior to assembly.

FIG. 6 shows a plan view illustration of the component parts from FIG. 5.

FIG. 7 shows a lateral illustration of an optoelectronic component constructed from the component parts from FIG. 5.

FIG. 8 shows a flow diagram illustrating steps of a method of producing an optoelectronic component.

FIG. 9 shows a lateral illustration of a carrier with a plurality of semiconductor chips, a silicone film and a ceramic conversion element prior to assembly, wherein the semiconductor chips have front side contacts.

FIG. 10 shows a plan view illustration of the component parts from FIG. 9.

FIG. 11 shows a lateral illustration of the carrier with the semiconductor chips and the silicone film arranged on the semiconductor chips, wherein a further layer surrounding the semiconductor chips and contact structures that contact the semiconductor chips are formed.

FIG. 12 shows a plan view illustration corresponding to FIG. 11.

FIG. 13 shows a lateral illustration of an optoelectronic component.

FIG. 14 shows a modified configuration relative to FIG. 11, wherein the silicone film laterally overlaps the semiconductor chips.

FIG. 15 shows a plan view illustration corresponding to FIG. 14.

FIG. 16 shows a lateral illustration of an optoelectronic component.

FIG. 17. shows a flow diagram illustrating steps of a further method of producing an optoelectronic component.

### LIST OF REFERENCE SIGNS

100, 101 Component

102, 103 Component

110, 111 Chip

112 Chip

115, 116 Contact

117 Contact

120 Carrier

130 Silicone film

131 Connection layer

135 Silicone film

137 Cutout

140 Conversion element

147 Cutout

151, 152 Contact structure

153, 154 Contact structure

160 Layer

201, 202 Method step

203, 204 Method step

205 Method step

### DETAILED DESCRIPTION

I provide a method of producing an optoelectronic component. The method comprises providing at least one optoelectronic semiconductor chip and arranging a starting layer on the semiconductor chip. The starting layer is present in the form of a film and comprises a first phosphor. The method furthermore involves arranging a conversion element on the starting layer, wherein the conversion element comprises a second phosphor. Provision is furthermore made to cure the starting layer to form a connection layer.

Instead of a liquid or viscous adhesive, a continuous starting layer present as a film is used in the method, the starting layer being positioned between the semiconductor chip(s) and the conversion element. The film-type starting layer, which comprises the first phosphor and is in a (still) non-cured state, can be provided with a predefined thickness. The connection layer emerging therefrom as a result of curing, which can be linked to the semiconductor chip(s) and to the conversion element in the context of curing, can have the predefined layer thickness in the same way. As a result, the light radiation emitted by the optoelectronic component during operation can correspond relatively accurately to predefined color parameters. Besides the thickness, the lateral dimensions of the starting layer and thus of the connection layer can also be reliably defined. The first phosphor comprised by the starting layer and thus by the connection layer can be present in the form of particles, for example.

The starting layer may be a partly crosslinked silicone film comprising the first phosphor. The partly crosslinked silicone film is crosslinked during curing. Such a film formed from partially crosslinked silicone, which can also be designated as a bi-stage silicone layer, can be produced with a high reliability and accuracy with a predefined thickness and with predefined lateral dimensions. For this purpose, provision can be made to provide a relatively large partly crosslinked silicone film in a frozen state, and cutting out or stamping therefrom a fragment or a lamina which can be coordinated with the lateral form of the semiconductor chip(s) and/or of the conversion element. In this case, as indicated above, the first phosphor can be contained in the form of particles in the silicone film.

Since silicone is an electrically insulating material, such a film or layer can, if appropriate, also be used as a reliable carrier of contact structures. This will be discussed in even greater detail further below.

Instead of partly crosslinked silicone, however, it is also possible to use some other insulating and curable material for the continuous film-like starting layer. This can involve in particular a partly crosslinked plastic or polymer material which can be crosslinked comparably to silicone by baking Such a material can contain the first phosphor as particle filling in the same way.

The conversion element may be a ceramic conversion element. In this case, provision can be made for the entire or substantially the entire conversion element to be formed from the second phosphor. The ceramic conversion element can enable an efficient heat dissipation during the operation of the optoelectronic component. A further possible advantage is that light scattering can be (largely) avoided.

The method can be used to produce an optoelectronic component embodied as a white light source. In this regard, the semiconductor chip may be designed to generate a light radiation in the blue to ultraviolet spectral range.

The optoelectronic semiconductor chip can be in particular a light emitting diode or LED chip.

To generate white light radiation, the first phosphor may be comprised by the starting layer and thus by the connection layer to be designed to convert part of the light radiation emitted by the semiconductor chip into a light radiation in the red spectral range. The second phosphor comprised by the conversion element converts part of the light radiation emitted by the semiconductor chip into a light radiation in the yellow to green spectral range. What can be achieved by additive color mixing is that the optoelectronic component emits a white, for example, warm-white, light radiation during operation.

Curing the film-type starting layer may comprise carrying out a thermal process. In one configuration of the starting layer as a partly crosslinked silicone film, the thermal process can be carried out, for example, at a temperature of 150° C. to 160° C.

In the method of producing an optoelectronic component, the film may comprise a cut-out or stamped-out bi-stage silicone layer. The starting layer can comprise a bi-stage silicone layer. The cut-out or stamped-out bi-stage silicone film can have traces of a material removal at side surfaces of the bi-stage silicone layer. The side surfaces of the bi-stage silicone layer run parallel to the thickness of the bi-stage silicone layer, wherein the thickness runs transversely, preferably perpendicularly, with respect to the lateral dimensions of the starting layer. The lateral dimensions run parallel to a light exit surface of the optoelectronic semiconductor chips. The bi-stage silicone layer can have a temperature of at least −18° C. in the partially crosslinked state and can crosslink at room temperature and/or higher temperatures.

The optoelectronic component can be realized with different semiconductor chips. By way of example, the semiconductor chip can have a front-side contact. In a manner coordinated therewith, the starting layer and the conversion element have a cutout for the front-side contact. Such a semiconductor chip having a front-side contact can have a relatively simple and cost-effective construction.

Besides the possibility of embodying the optoelectronic component in the form of a single-chip component, production in the form of a multi-chip component or module may also be appropriate. A further example in this regard provides for an arrangement comprising a plurality of optoelectronic semiconductor chips to be provided, and for the starting layer to be arranged on the plurality of semiconductor chips.

A multi-chip module can be realized with semiconductor chips which only have rear-side contacts. As a result, an entire front side of the semiconductor chips can be utilized to emit a light radiation. Such a configuration may also be appropriate for a single-chip component.

An alternative involves producing a multi-chip module comprising a plurality of semiconductor chips which have two front-side contacts. In this example contact structures are formed in the starting layer, via which front-side contacts of semiconductor chips, in particular of adjacent semiconductor chips, electrically connect to one another. This enables simple contacting of semiconductor chips. Via the contact structures, the semiconductor chips can electrically connect to one another in series, for example.

An insulating layer may be formed, on (or in) which contact structures that contact the semiconductor chips are arranged. This can involve, in particular, contact structures via which a series connection of semiconductor chips can be contacted at the ends. The insulating layer can be, for example, in the form of a layer surrounding the plurality of semiconductor chips.

The semiconductor chip or the semiconductor chips may be or are arranged on a carrier. This method step can be carried out before the starting layer is arranged on the semiconductor chip(s). The carrier can be a ceramic carrier, for example. Other carriers which can comprise a heat sink, for example, are also possible. The carrier can have electrical connection and contact structures.

I also provide an optoelectronic component. The optoelectronic component comprises a carrier, at least one optoelectronic semiconductor chip arranged on the carrier, and a connection layer arranged on the semiconductor chip. The connection layer comprises a first phosphor. The optoelectronic component furthermore comprises a conversion element comprising a second phosphor, the conversion element being arranged on the connection layer. The connection layer is formed by curing a film-type starting layer comprising the first phosphor. As a result, the connection layer can have a predefined layer thickness as a result of which a light radiation emitted by the optoelectronic component can correspond to predefined color parameters, and the component can have a high color locus accuracy.

The starting layer may comprise a bi-stage silicone layer and traces of a material removal are formed at side surfaces of the bi-stage silicone layer. The side surfaces of the bi-stage silicone layer run in particular transversely with respect to a lateral extent of the starting layer, wherein the lateral extent of the starting layer runs parallel to a light exit surface of the optoelectronic semiconductor chip. By way of example, the traces of the material removal on the side surfaces of the bi-stage silicone layer can be attributed to a cutting and/or stamping method. The bi-stage silicone layer can have a temperature of at least −18° C. in the partially crosslinked state and can crosslink at room temperature and/or higher temperatures.

Examples and aspects specified above with respect to the method may be appropriate in the same way for the optoelectronic component.

The above-described properties, features and advantages and the way in which they are achieved will become clearer and more clearly understood in association with the following description of examples explained in greater detail in association with the schematic drawings.

Examples of a method of producing optoelectronic components which can correspond to predefined color properties with a high reliability and accuracy are described on the basis of the following schematic figures. The components, which can also be designated as chip modules or packages, can be realized in the form of white light sources and emit a white, in particular warm-white, light radiation during operation.

In the method, processes known in semiconductor technology and in the manufacture of optoelectronic components can be carried out and conventional materials can be used such that these are discussed only in part. It is furthermore pointed out that besides the processes described and illustrated, further method steps can be carried out, if appropriate, to complete production of the respective components. In the same way, the components can comprise further structures and structure elements besides structures described and shown.

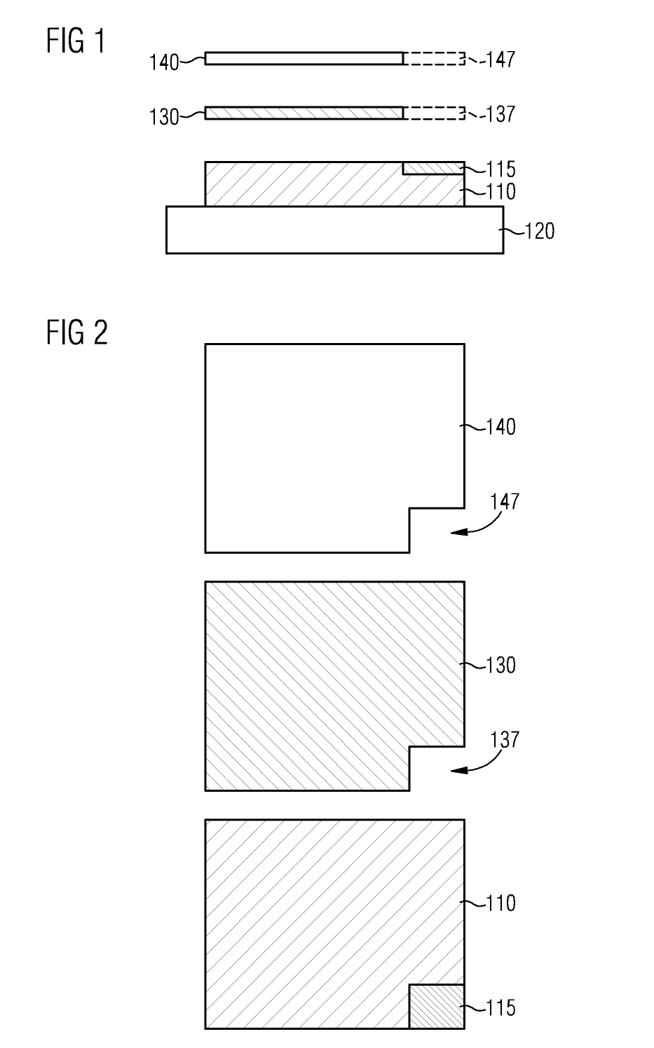

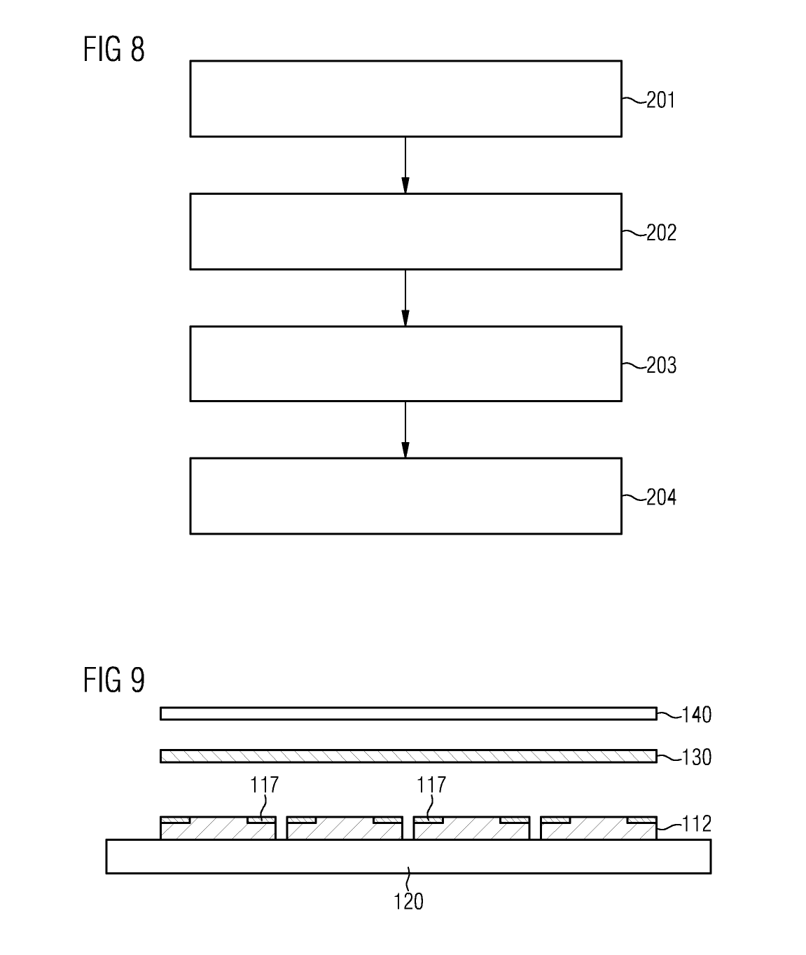

The production of a first optoelectronic component 100 is described with reference to schematic FIGS. 1 to 4, the optoelectronic component constituting a single-chip component 100. Method steps carried out in the method are supplementarily summarized in the flow diagram from FIG. 8, to which reference is likewise made hereinafter.

In the method, a step 201 (cf. FIG. 8) involves providing an optoelectronic semiconductor chip 110, which is shown from the side in FIG. 1 and in plan view in FIG. 2. The semiconductor chip 110 is a light emitting diode or LED chip 110, in particular. The semiconductor chip 110 emits light radiation upon application of an electric current during operation. With regard to a configuration of the optoelectronic component 100 to be produced as a white light source, the semiconductor chip 110 emits light radiation in the blue to ultraviolet wavelength range.

For application of the electric current, the semiconductor chip 110 can be contacted both at a front side and at a rear side opposite the front side. With regard to the front side, the semiconductor chip 110, as shown in FIGS. 1 and 2, has a metallic contact 115 arranged at the edge or at a corner. The front-side contact 115 can be, for example, a metallic contact area (bonding pad) suitable for wire bonding. The front side of the semiconductor chip 110 simultaneously emits the light radiation (light exit side). At the opposite rear side, the semiconductor chip 110 has a metallic rear-side contact (not illustrated).

The semiconductor chip 110 may have a carrier substrate and a useful layer or useful layer arrangement (not illustrated) arranged on the front side. The useful layer comprises a semiconductor layer sequence having an active zone suitable for emitting radiation. In this case, the front-side contact 115 is arranged on the useful layer, and the rear-side contact is arranged on the carrier substrate. The two contacts electrically connect to different sides of the semiconductor layer sequence.

In the context of step 201 (cf. FIG. 8), provision is furthermore made to arrange the provided semiconductor chip or LED chip 110 as shown in FIG. 1 on a carrier 120. The carrier 120, which can also be designated as a submount, has electrical connection and contact structures for the chip 110 (not illustrated).

The carrier 120 can have in particular a metallic mating contact coordinated with the rear-side contact of the semiconductor chip 110. Upon the semiconductor chip 110 being arranged on the carrier 120, these contacts are electrically and mechanically connected. This can be carried out by soldering using a solder material. The carrier 120 can furthermore have a further mating contact, to which a bonding wire provided to contact the front-side contact 115 of the chip 110 can be connected.

The carrier 120 can be, for example, a ceramic carrier 120. Alternatively, a different configuration may be appropriate. By way of example, the carrier 120 can have a metallic heat sink, wherein the heat sink and in part corresponding contact or conductor track structures are surrounded by a plastic material (premold carrier).

In the context of step 201 (cf. FIG. 8), provision is made of further component parts shown in FIGS. 1 and 2 for production of the optoelectronic component 100. This involves a laminar segment of a continuous film 130 composed of partially crosslinked silicone and a laminar ceramic conversion element 140. As is shown in FIG. 2, the silicone film 130 and the conversion element 140 have substantially the same lateral dimensions as the semiconductor chip 110 and are at the edge or at a corner with a cutout 137, 147 coordinated with the front-side contact 115 of the semiconductor chip 110.

The silicone film 130 formed from partly crosslinked silicone is used, on the one hand, to fix the conversion element 140 on the semiconductor chip 110 and for this purpose, as described in greater detail further below, it is converted into a corresponding connection layer 131 (cf. FIG. 4). On the other hand, the silicone film 130 and the connection layer 131 emerging therefrom convert part of the light radiation of the semiconductor chip 110.

In this regard, the silicone film 130 comprises a first conversion material or a first phosphor, with the aid of which part of the primary light radiation emitted by the semiconductor chip 110 via the front side thereof can be converted into a secondary light radiation. With regard to the configuration of the component 100 as a white light source, a secondary light radiation in the red spectral range is appropriate. The first phosphor can be a nitride-based phosphor, for example. The first phosphor can be contained in the form of particles in the silicone film 130.

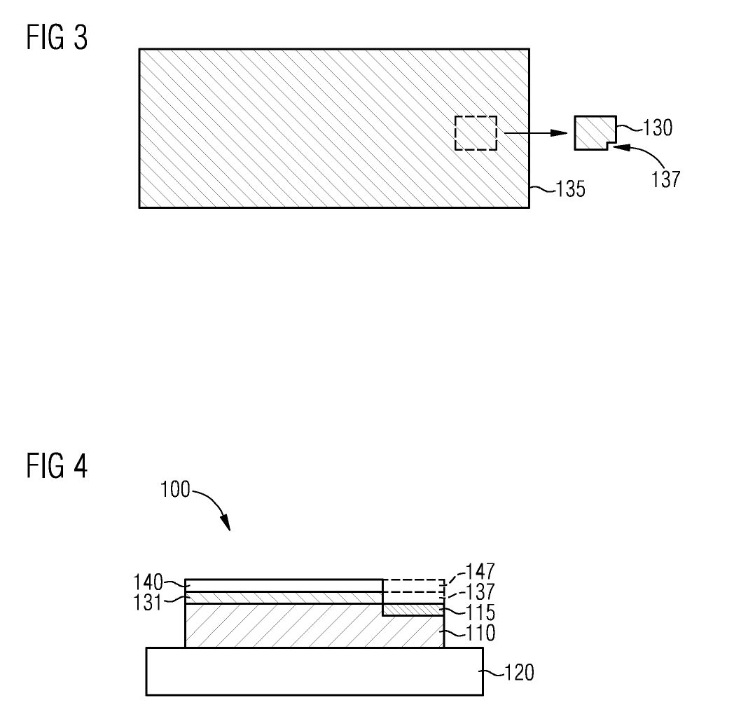

The silicone film 130 provided for the component 100 can be produced by a procedure in which, first, as shown in FIG. 3, a large-area film 135 composed of partially crosslinked silicone is produced, which is filled with particles of the first phosphor. A molding method can be carried out for this purpose. This affords the possibility of controlling the height or thickness and the height variation of the silicone film 135 with a high accuracy, as a result of which the silicone film 135 and, hence, also the partial film 130 for the component 100, can be produced with a predefined layer thickness. The silicone film 135 with phosphor particle filling can have a uniform thickness, for example, which is 50 μm to 150 μm.

The partly crosslinked silicone film 135 is stored in a frozen state, for example, at a temperature of −18° C., and so a further crosslinking of the silicone such as is not envisaged until in a later method stage, can be avoided. A further crosslinking can be carried out at room temperature or (even) higher temperatures. Such a film which is in a precrosslinked state and which can be fully crosslinked in a targeted manner is also designated as a bi-stage silicone film.

As is furthermore indicated in FIG. 3, the silicone film lamina 130 provided for the component 100 can be obtained by cutting-out or stamping from the large-area silicone film 135. This is possible with a high accuracy on account of the frozen state. The silicone film 130 can thus be reliably produced with a lateral form which corresponds to the conversion element 140 and is coordinated with the semiconductor chip 110. In accordance with the silicone film 135, the partial film 130 obtained therefrom can have a predefined layer thickness. These advantageous aspects, i.e. the presence of a predefined accurate form and layer thickness, apply in the same way to the connection layer 131 produced from the silicone film 130.

With regard to the cutting-out or stamping, it can be provided that a plurality of partial films 130 for a corresponding plurality of components 100 to be produced are produced simultaneously or successively from the large-area silicone film 135.

The ceramic conversion element 140, likewise provided in the context of step 201, comprises a second conversion material or a second phosphor, with the aid of which part of the primary light radiation emitted by the semiconductor chip 110 can likewise be converted into a secondary light radiation. With regard to the configuration of the component 100 as a white light source, a secondary light radiation in the yellow to green spectral range is involved. Provision can be made for substantially the entire conversion element 140 to be formed from the second phosphor. By way of example, a configuration based on YAG (Yttrium Aluminum Garnet) or LuAG (Lutetium Aluminum Garnet) is appropriate. The production of the ceramic conversion element 140 can comprise, for example, sintering the second phosphor, which is initially provided in powder form.

The use of the ceramic conversion element 140 affords the advantage of enabling an efficient heat dissipation during the operation of the optoelectronic component 100. A further possible advantage is that no or only relatively little light scattering occurs.

In a further step 202 (cf. FIG. 8), these component parts are arranged one above another in the form of a stack, that is to say that the silicone film 130 is positioned on the semiconductor chip 110 (or the front side thereof) and the ceramic conversion element 140 is positioned on the silicone film 130 (cf. FIGS. 1 and 4). The arrangement of these component parts is carried out such that no or only negligible crosslinking of the silicone film 130 takes place. Preferably, therefore, the silicone film 130 is still in a frozen state, or in an only slightly thawed state.

In a subsequent step 203 (cf. FIG. 8), the silicone film 130 is cured as a result of which the silicone film 130 can be converted into the connection layer 131, and the component 100 shown in FIG. 4 can be provided as a result. For this purpose, a thermal process is carried out, for example, with a baking temperature of 150° C. to 160° C. The baking has the consequence that the silicone initially present in partly crosslinked form is crosslinked to completion or completely crosslinked throughout. A linking of the silicone to the semiconductor chip 110 and to the conversion element 140 furthermore takes place during the crosslinking step. In this way, the cured connection layer 131 that has emerged from the silicone film 130 ensures that the conversion element 140 fixedly connects to the semiconductor chip 110.

After this, further processes (not illustrated) to complete the optoelectronic component 100 can be carried out, which are summarized in a further step 204 in the flow diagram in FIG. 8. They include, for example, fitting a bonding wire to the front-side contact 115 of the semiconductor chip 110 and to the associated mating contact of the carrier 120. On account of the cutouts 137, 147 of the silicone film 130 and of the conversion element 140, the front-side contact 115 is freely accessible for this process. Further possible processes include, for example, potting the component 100, arranging a lens or the like.

As indicated above, the optoelectronic component 100 can be a white light source. In this case, the superimposition of the different partial radiations, i.e. in the blue or ultraviolet primary radiation of the semiconductor chip 110, the red secondary radiation generated with the aid of the phosphor particles of the connection layer 131 and the yellow-green secondary radiation of the conversion element 140, can result in a white or warm-white light radiation. Since the partly crosslinked silicone film 130 serving as a starting layer, and as a result the connection layer 131 can have a predefined layer thickness, color parameters of the optoelectronic component 100, in particular the color locus of the emitted light radiation, can be defined with a high reliability and accuracy.

Further optoelectronic components and possible methods of producing them are described with reference to the following figures. With regard to details already described which relate to component parts and features of identical type or corresponding component parts and features, possible advantages and the like, reference is made to the above explanations. It is furthermore possible that features and aspects mentioned with regard to one of the following examples can also be applied to other examples from among those described below.

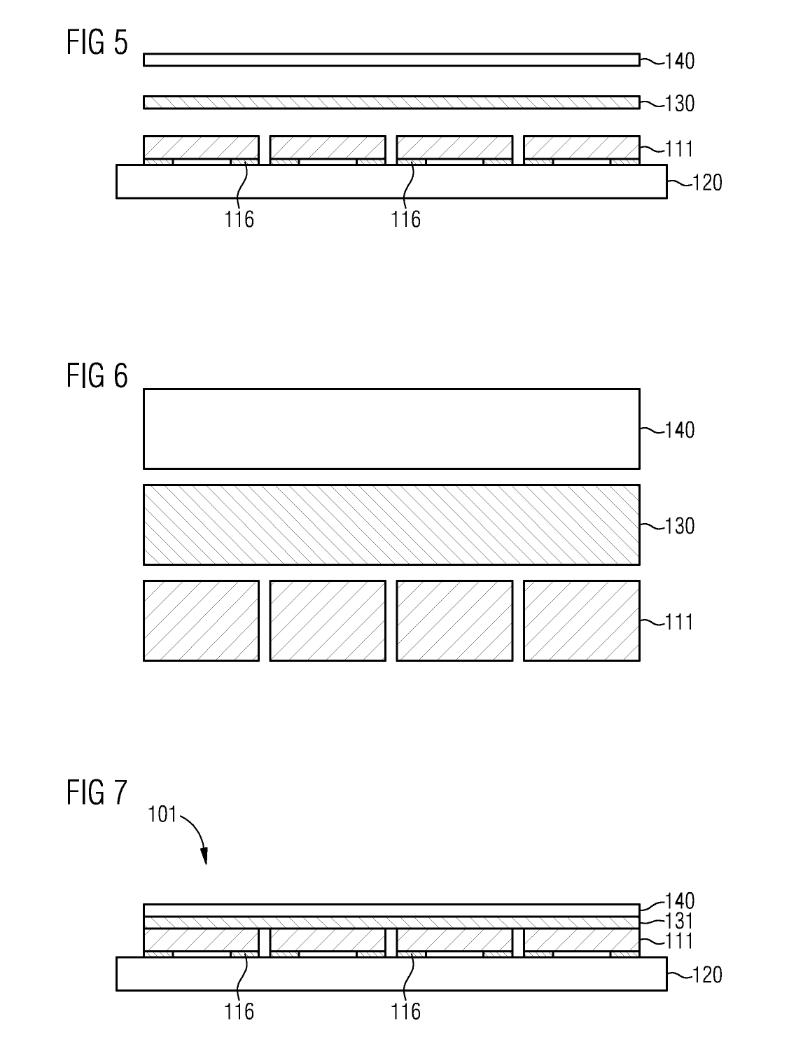

The method can be used not just to produce single-chip components, but in the same way to produce components comprising a plurality of chips, which can also be designated as multi-chip components or multi-chip modules. One possible example is production of an optoelectronic component 101 as illustrated in schematic FIGS. 5 to 7, the optoelectronic component constituting such a multi-chip component 101. Method steps carried out in the method are likewise summarized in the flow diagram from FIG. 8.

In the method, a step 201 (cf. FIG. 8) involves providing a plurality of optoelectronic semiconductor chips 111, for example, four thereof as shown in FIGS. 5 and 6. The semiconductor chips 111 constitute in particular LED chips 111. With regard to a configuration of the optoelectronic component 101 to be produced as a white light source, the chips 111 emit light radiation in the blue to ultraviolet spectral range.

As is shown in FIG. 5, the individual semiconductor chips 111 have two metallic contacts 116, via which an electric current can be applied to the chips 111 during operation. The contacts 116 are arranged at the rear side of the chips 111 opposite the front side (light exit side). The rear-side contacts 116 can be realized, for example, in the form of contact areas, wire contacts or contact elevations (bumps). Furthermore, provision can be made for the rear-side contacts 116 to be provided with a solder material, for example, in the form of solder balls, in the context of providing the semiconductor chips 111.

The semiconductor chips 111 may have a carrier substrate and a useful layer or useful layer arrangement (not illustrated) arranged on the front side. The useful layer comprises a semiconductor layer sequence having an active zone that emits radiation. In this case, the rear-side contacts 116 of a chip 111 are arranged on the carrier substrate and electrically connected to different sides of the semiconductor layer sequence.

In the context of step 201 (cf. FIG. 8), the semiconductor chips or LED chips 111 provided are arranged on a carrier 120 as shown in FIG. 5. In that configuration, the chips 111 are positioned alongside one another in the form of a line or row on the carrier 120, as also indicated in the plan view illustration in FIG. 6.

The carrier 120 can be, for example, a ceramic carrier or some other carrier such as a premold carrier, for example. The carrier 120 has connection and contact structures coordinated with the chips 111 (not illustrated). These include metallic mating contacts corresponding to the rear-side contacts 116 of the chips 111. Upon the semiconductor chips 111 being arranged on the carrier 120, these contacts are electrically and mechanically connected, which can be carried out in the context of soldering using a solder material.

In the context of step 201 (cf. FIG. 8), a partly crosslinked silicone film 130 and a ceramic conversion element 140 are furthermore provided. As is indicated in FIG. 6, these laminar component parts 130, 140 have in each case the same elongate rectangular or strip form. This form is coordinated with the arrangement of the chips 111 on the carrier 120 to be able to position both component parts 130, 140 on the plurality of chips 111.

The partly crosslinked silicone film 130 can be produced in the manner described above, i.e. by cutting-out or stamping from a (frozen) large-area silicone film (not illustrated). As a result, the silicone film 130 can be produced relatively accurately with a predefined form and thickness. The silicone film 130 comprises a first phosphor, with the aid of which part of the primary light radiation emitted by the semiconductor chips 111 can be converted into a secondary light radiation. With regard to the configuration of the component 101 as a white light source, a red light radiation is appropriate. The first phosphor can be contained in the form of particles in the silicone film 130.

The ceramic conversion element 140 comprises a second phosphor with the aid of which part of the primary light radiation emitted by the semiconductor chips 111 can likewise be converted into a secondary light radiation. With regard to the configuration of the component 101 as a white light source, a yellow or green light radiation is appropriate. Substantially the entire conversion element 140 can be formed from the second phosphor.

In a further step 202 (cf. FIG. 8), these component parts are stacked one above another, that is to say that the silicone film 130 is placed on the semiconductor chips 111 (or the front sides thereof) and the ceramic conversion element 140 is placed on the silicone film 130 (cf. FIGS. 5 and 7). In this case, the silicone film 130 is preferably in a frozen or only slightly thawed state such that as yet no or only negligible crosslinking of the silicone film 130 can take place.

In a subsequent step 203 (cf. FIG. 8), the silicone film 130 is converted into a fully crosslinked connection layer 131 by baking During crosslinking, the silicone is linked both to the semiconductor chips 111 and to the conversion element 140. In this way, in the component 101 shown in FIG. 7, the conversion element 140 fixedly connects to the semiconductor chips 111 via the cured connection layer 131.

Afterward, further processes (not illustrated) to complete the optoelectronic component 101 can be carried out (step 204 in FIG. 8). By way of example, potting the component 101, arranging a lens and the like are appropriate.

The optoelectronic component 101 can also be a white light source. In this case, a white or warm-white light radiation can be generated by superimposition of the blue or ultraviolet primary radiation of the semiconductor chips 111, the red secondary radiation of the connection layer 131 and the yellow-green secondary radiation of the conversion element 140. Since the connection layer 131 can have a defined layer thickness, the light radiation can reliably correspond to a predefined color locus.

Besides the functions described above—fixing a conversion element 140 and radiation conversion—a cured connection layer 131 can also be used as a carrier of (recessed) contact structures. Examples are described in greater detail below.

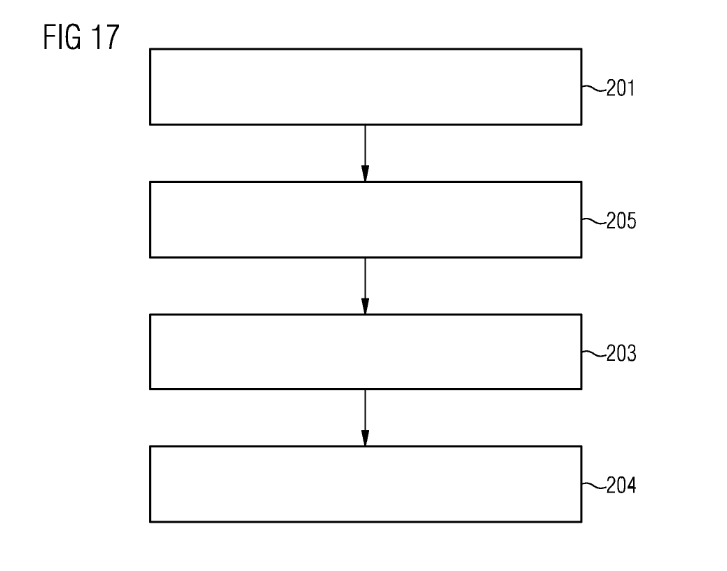

Schematic FIGS. 9 to 13 illustrate production of a further multi-chip component 102. Method steps carried out in the method are supplementarily summarized in the flow diagram from FIG. 17, to which reference is likewise made below.

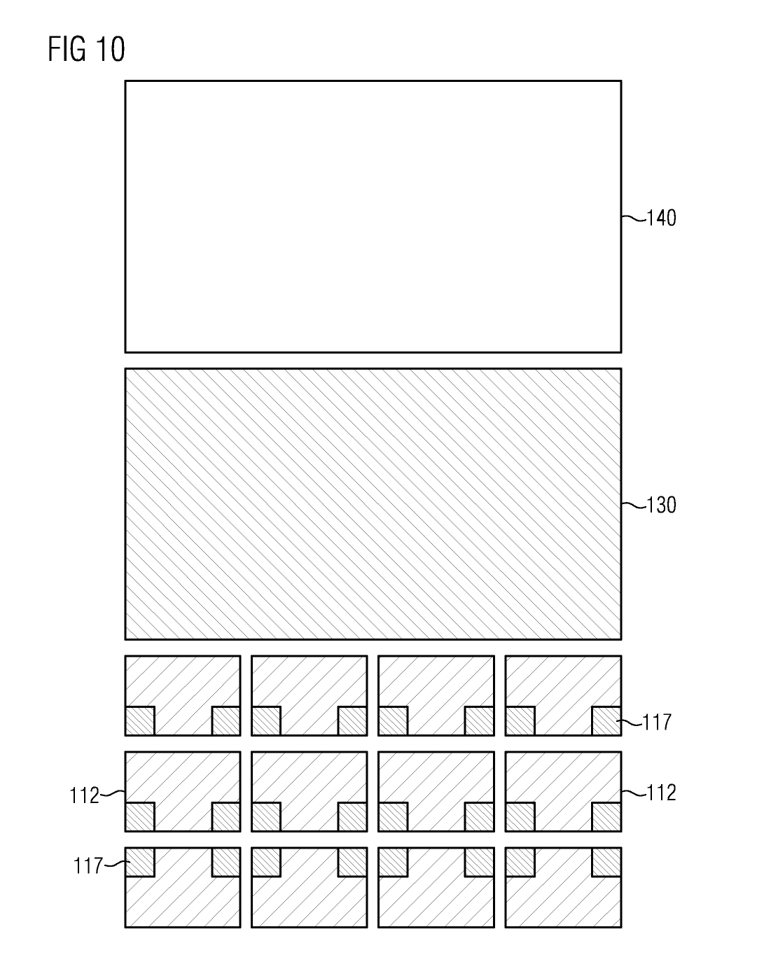

In the method, a step 201 (cf. FIG. 17) involves providing a plurality of semiconductor chips 112, for example, twelve thereof as shown in FIG. 10. These are LED chips 112, in particular. With regard to a configuration of the optoelectronic component 102 to be produced as a white light source, the chips 112 emit a light radiation in the blue to ultraviolet spectral range. As shown in FIGS. 9 and 10, the individual chips 112 have two metallic contacts 117, via which an electric current can be applied to the chips 112 during operation. The contacts 117 are arranged at the edge or at corners of the front side (light exit side) of the chips 112. The front-side contacts 117 can be realized, for example, in the form of contact areas.

The semiconductor chips 112 may have a carrier substrate and a useful layer or useful layer arrangement arranged on the front side (not illustrated). The useful layer comprises a semiconductor layer sequence having an active zone that emits radiation. In this case, the front-side contacts 117 are arranged on the useful layer. The front-side contacts 117 furthermore electrically connect to different sides of the semiconductor layer sequence.

In the context of step 201 (cf. FIG. 17), the semiconductor chips or LED chips 112 provided are arranged on a carrier 120 as shown in FIG. 9. In the configuration shown here, the chips 112 are positioned in the form of a matrix, i.e. in the form of rows and columns, on the carrier 120 (cf. FIGS. 10 and 12). In this case, the front-side contacts 117 of a row of chips 112 in each case lie on a common line which is chosen with regard to contacting of the chips 112 that is to be produced.

The carrier 120 can be, for example, a ceramic carrier, or some other carrier such as, for example, a premold carrier comprising a heat sink. During the arranging process, the semiconductor chips 112 only mechanically connect to the carrier 120. This can be carried out in the context of soldering using a solder material. To promote production of the solder connection, the semiconductor chips 112 and the carrier 120 can have metallic layers coordinated with one another. In the chips 112, the layers can be provided (not illustrated) on the rear side (or on the carrier substrate).

In the context of step 201 (cf. FIG. 17), a partly crosslinked silicone film 130 and a ceramic conversion element 140 are furthermore provided. As is indicated in FIG. 10, the two laminar component parts 130, 140 have a rectangular form with corresponding lateral dimensions. This form is coordinated with the arrangement of the chips 112 on the carrier 120 to position both component parts 130, 140 on the plurality of chips 112. In the configuration shown, provision is furthermore made for the silicone film 130 arranged (subsequently) on the chips 112 to extend to the edge of the chips 112 (cf. FIG. 12).

The partly crosslinked silicone film 130 can be produced in the manner described above, i.e. by cutting-out or stamping from a (frozen) large-area silicone film (not illustrated). As a result, the silicone film 130 can be produced relatively accurately with a predefined form and thickness. The silicone film 130 comprises a first phosphor, with the aid of which part of the primary light radiation emitted by the semiconductor chips 112 can be converted into a secondary light radiation. With regard to the configuration of the component 102 as a white light source, a red light radiation is appropriate. The first phosphor can be contained in the form of particles in the silicone plate 130.

The ceramic conversion element 140 comprises a second phosphor, with the aid of which part of the primary light radiation emitted by the semiconductor chips 112 can likewise be converted into a secondary light radiation. With regard to the configuration of the component 102 as a white light source, a yellow or green light radiation is appropriate. Substantially the entire conversion element 140 can be formed from the second phosphor.

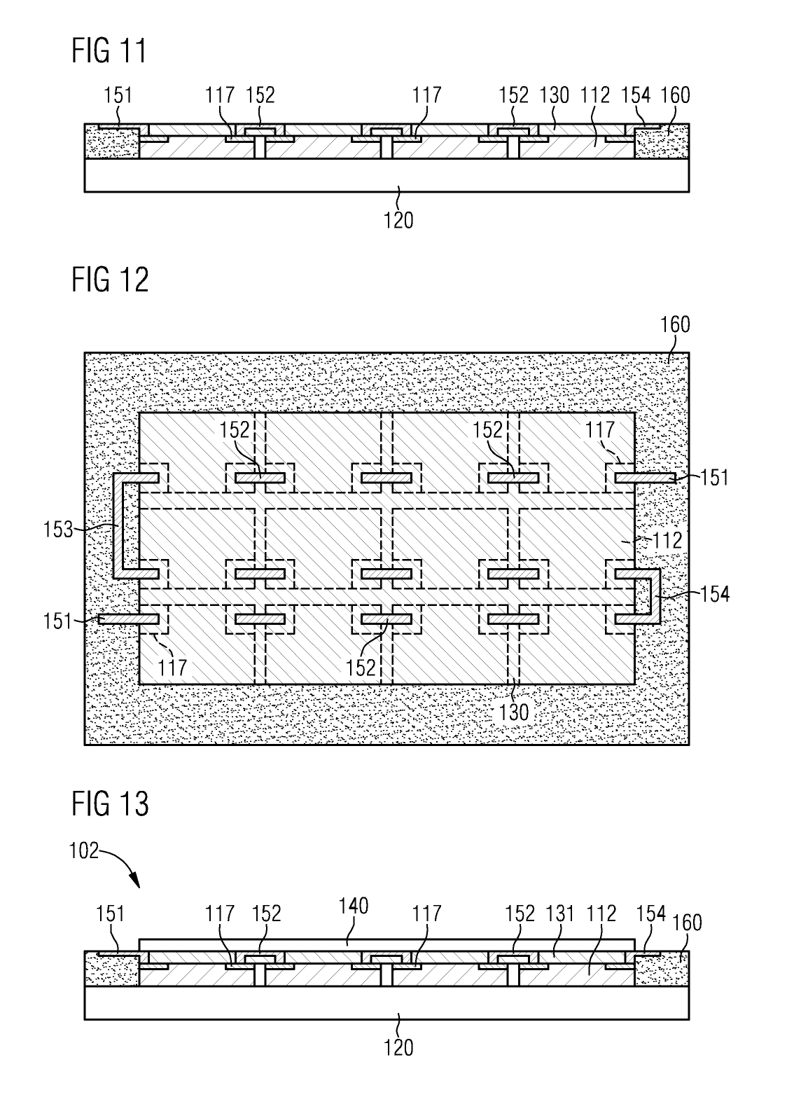

A further step 205 (cf. FIG. 17) involves forming metallic contact structures 151, 152, 153, 154, with the aid of which the semiconductor chips 112 can be contacted (cf. the schematic lateral sectional illustration in FIG. 11 and the plan view illustration in FIG. 12). Before actual production of the structures 151, 152, 153, 154, in step 205, first, the silicone film 130 is arranged on the semiconductor chips 112 (or on the front sides thereof). In this case, as illustrated in FIG. 12, the silicone film 130 projects to the edge of the chips 112. The chips 112 and the front-side contacts 117 thereof are indicated with the aid of dashed lines in FIG. 12.

Before formation of the contact structures 151, 152, 153, 154, furthermore, a further layer 160 is arranged or formed on the carrier 120. The plurality of semiconductor chips 112 and the silicone film 130 arranged thereon are surrounded by the layer 160 as shown in FIGS. 11 and 12. The layer 160 can directly adjoin the chips 112 and the silicone film 130, and terminate (substantially) flush with the silicone film 130 on the front side. The layer 160 comprises an insulating material, in a manner comparable to the silicone film 130 and the connection layer 131 emerging therefrom.

The layer 160 can be a silicone layer, for example. The use of white silicone containing titanium oxide particles is appropriate, for example. The process of arranging the layer 160 on the carrier 120 that is carried out in step 205 can be implemented before or else after placement of the silicone film 130 on the semiconductor chips 112.

One possible procedure consists, for example, of the layer 160 being applied to the carrier 120 in liquid form and cured after the process of arranging the semiconductor chips 112 on the carrier 120, that is to say before the process of arranging the silicone film 130 on the chips 112. Alternatively, it may be appropriate for the already cured layer 160 having a frame-shaped or enclosing form to be adhesively bonded onto the carrier 120, for example, which can be carried out before or else after a process of arranging the silicone film 130 on the chips 112. Furthermore, it is possible for the layer 160 to constitute a (further) partly crosslinked bi-stage silicone layer (without phosphor), which can be crosslinked together with the silicone film 130 in a later method stage, and thereby be linked to the carrier 120. A further possible variant consists of the carrier 120 with the layer 160 arranged thereon already being provided in the context of step 201, that is to say before the semiconductor chips 112 are arranged on the carrier 120.

As is furthermore shown in FIGS. 11 and 12, the subsequently produced contact structures 151, 152, 153, 154 are formed within the silicone film 130 and on or in the surrounding layer 160. The contact structures 151, 152, 153, 154, which contact the front-side contacts 117 of the semiconductor chips 112 electrically connect the semiconductor chips 112 to one another in the form of a series circuit, and enable contacting of the series circuit formed therefrom at the ends. An S-shaped series connection is provided in this case.

With reference to FIG. 12, it becomes clear that respectively adjacent semiconductor chips 112 in a row electrically connect to one another via relatively short contact structures 152. At the edge of the chip arrangement, U-shaped contact structures 153, 154 in plan view are present, with the aid of which adjacent chips 112 of different rows connected to one another. Further contact structures 151, illustrated as elongate and extending laterally away from the chip arrangement contact the ends of the series circuit. The contact structures 151 can constitute in particular conductor track structures arranged on the layer 160. In this case, the structures 151 shown in FIGS. 11 to 13 can be end-side partial sections of the conductor track structures.

Furthermore, as indicated in FIG. 11, the contact structures 151, 152, 153, 154 are recessed structures in the silicone film 130 and in the layer 160. In this case, the contact structures 151, 152, 153, 154 adjoin a top side of the silicone film 130 and of the layer 160 and form with these two layers 130, 160 a common planar surface. The recessed configuration enables (subsequently) planar bearing of the conversion element 140.

With regard to the conductor track structures described above and indicated on the basis of the sections 151, the recessed configuration can only be provided for the sections 151 shown in FIGS. 11 to 13. Other conductor track sections (not shown) can be arranged in a manner offset upwardly with respect thereto on the layer 160.

The contact structures 151, 152, 153, 154, which can be present in the form of a so-called CPHF metalization (Compact Planar High Flux), enable simple electrical contacting of the semiconductor chips 112. As a result, in particular, the carrier 120 can have a relatively simple construction, i.e. without contact structures for the chips 112.

The contact structures 151, 152, 153, 154 can be produced by the silicone film 130 and the layer 160 first being structured, for example, using a laser. Openings extending to the front-side contacts 117 of the semiconductor chips 112, and cutouts or trenches coordinated with the (lateral) form of the contact structures 151, 152, 153, 154 to be produced are produced in this case. A metallic material is subsequently applied, wherein the openings and cutouts are metallically filled.

This process can comprise, for example, carrying out an electroplating method. For this purpose, provision can be made to form a seed layer on the silicone film 130 and the layer 160, to mask the seed layer outside the contact structures 151, 152, 153, 154 to be produced by a photoresist, for example, and then depositing a metal electrochemically. In this case, deposition takes place only at non-masked locations on the seed layer. Afterward, the masking can be removed, and the seed layer can be removed outside the contact structures 151, 152, 153, 154 by etching. By way of example, copper may be appropriate as material for the seed layer and the deposited metal.

Step 205 furthermore involves arranging the ceramic conversion element 140 on the silicone film 130 (cf. FIG. 13). This process, and also the above-described processes carried out in the context of step 205, are carried out such that no, or only negligible crosslinking of the silicone film 130 (and of the layer 160 possibly present in partly crosslinked form) takes place.

In a subsequent step 203 (cf. FIG. 17), baking is carried out as a result of which the partly crosslinked silicone film 130 is converted into the fully crosslinked connection layer 131 in the manner described above, and the component 102 shown laterally in sectional view in FIG. 13 is provided as a result. In this case, the silicone is linked to the semiconductor chips 112, to the contact structures 151, 152, 153, 154 and to the conversion element 140. If the layer 160 is likewise initially present as a partly crosslinked silicone layer, the crosslinking that takes place during baking results in linking to the carrier 120 and to the contact structures 151, 153, 154.

Afterward, further processes (not illustrated) to complete the optoelectronic component 102 can be carried out (step 204 in FIG. 17). By way of example, potting the component 102, arranging a lens, connecting the contact structures 151 to further contact or connection structures and the like are appropriate.

The optoelectronic component 102 can likewise be a white light source. In this case, a white or warm-white light radiation can be generated by superimposition of the blue or ultraviolet primary radiation of the semiconductor chips 112, the red secondary radiation of the connection layer 131 and the yellow-green secondary radiation of the conversion element 140. Since the connection layer 131 can have a predefined layer thickness, the light radiation can reliably correspond to a predefined color locus.

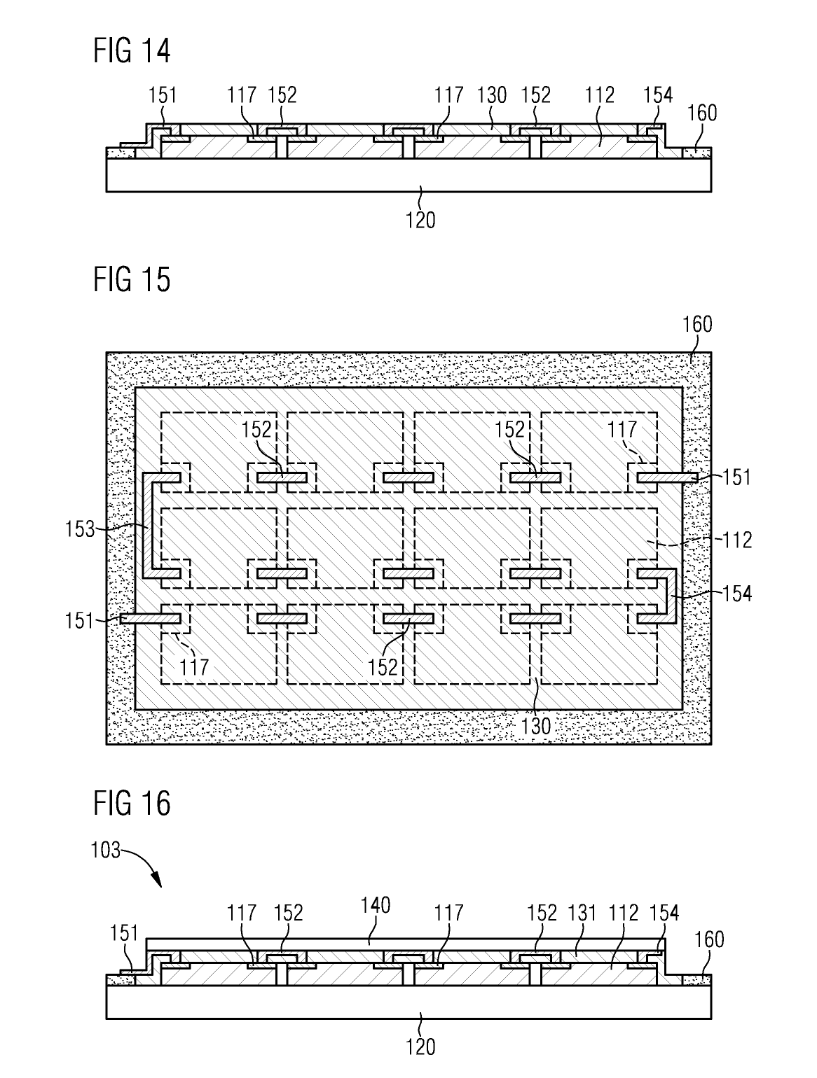

Production of a further multi-chip component 103 is described below with reference to schematic FIGS. 14 to 16, the component having substantially the same construction as the component 102 described above. In this case, reference is likewise made to the flow diagram from FIG. 17.

In the method, a step 201 (cf. FIG. 17) involves providing a plurality of optoelectronic semiconductor chips or LED chips 112, once again twelve thereof as shown in the plan view in FIG. 15, having two front-side contacts 117. The semiconductor chips 112 are arranged in the form of a matrix on a carrier 120, as shown in the lateral sectional illustration in FIG. 14 and in the plan view illustration in FIG. 15.

Step 201 (cf. FIG. 17) furthermore involves providing a rectangular partly crosslinked silicone film 130 comprising a first phosphor, and a rectangular ceramic conversion element 140 comprising a second phosphor. In contrast to the component 102 described above, the silicone film 130 provided for the component 103 has lateral dimensions such that the silicone film 130 arranged (subsequently) on the semiconductor chips 112 projects laterally beyond the edge of the chips 112 (cf. FIGS. 14 and 15). Moreover, the silicone film 130 has larger lateral dimensions than the conversion element 140.

In the context of a further step 205 (cf. FIG. 17), the silicone film 130 is arranged on the semiconductor chips 112. In this case, as is illustrated in FIGS. 14 and 15, the silicone film 130 laterally overlapping the semiconductor chips 112 at the edge is also arranged laterally with respect to the semiconductor chips 112 and in part on the carrier 120 and, therefore, has a stepped form at the edge. This can be realized by corresponding deformation or bending of the silicone film 130 after positioning thereof on the semiconductor chips 112. Deformation can be carried out in a thawed and hence deformable state of the silicone film 130.

As is shown in FIGS. 14 and 15, for the component 103 a further insulating layer 160 is likewise arranged or formed on the carrier 120, which further insulating layer encloses the plurality of semiconductor chips 112 and the silicone film 130 and can directly adjoin the silicone film 130. The layer 160 has a relatively small layer thickness which can correspond to the thickness of the silicone film 130. For the layer 160, details mentioned above concerning the production of the component 102 (for example, configuration as white silicone layer, formation of the layer 160 before or after arrangement of the silicone film 130 or the like) can be applied analogously.

This correspondingly holds true for formation-carried out in the context of step 205 (cf. FIG. 17)—of metallic contact structures 151, 152, 153, 154 within the silicone film 130 and on the surrounding layer 160. In contrast to the component 102, the U-shaped contact structures 153, 154—like the relatively short contact structures 152—are arranged only in the region of the silicone film 130 (cf. FIG. 15). Furthermore, the contact structures 151 provided to contact the ends of the series connection of the chips 112 have as shown in FIG. 14, a stepped shape predefined by the stepped form of the silicone film 130. The contact structures 151, which can constitute conductor track structures or end-side partial sections of such conductor track structures, are recessed in this case only in a partial region of the silicone film 130.

Step 205 furthermore involves arranging the ceramic conversion element 140 on the silicone film 130 (cf. the lateral sectional illustration in FIG. 16). Afterward, baking is carried out in a step 203 (cf. FIG. 17), as a result of which the partly crosslinked silicone film 130 converts into the fully crosslinked connection layer 131 in the manner described above. If the layer 160 is likewise present as a partly crosslinked silicone layer, the latter is likewise completely crosslinked by the baking Afterward, further processes (not illustrated) to complete the optoelectronic component 103 from FIG. 16 can be carried out (step 204 in FIG. 17). The optoelectronic component 103 can likewise be realized as a white light source.

The examples explained with reference to the figures constitute preferred or exemplary configurations. Besides the examples described and illustrated, further examples are possible which can comprise further modifications and/or combinations of features. By way of example, other materials can be used instead of the materials specified above, and numerical indications above with regard to layer thicknesses, temperatures and the like can be replaced by other indications.

One possible combination consists, for example, of constructing the single-chip component 100 shown in FIG. 4 with a semiconductor chip 111 having only rear-side contacts 116 (cf. FIGS. 5 and 7). As a result, the silicone film 130 and the conversion element 140 of such a component can be realized with a rectangular form without cutouts 137, 147.

Furthermore, there is the possibility of producing multi-chip modules having a different number and/or having different geometrical arrangements of semiconductor chips on a carrier 120. By way of example, the component 101 from FIG. 7 can be realized with a matrix arrangement of chips 111. Furthermore, the components 102, 103 in FIGS. 13 and 16 can be constructed with, for example, chips 112 arranged only on a line and connected in series by contact structures. Different numbers of chips and/or forms of chip arrangements can correspondingly result in different forms of silicone films 130 and conversion elements 140 to be able to position these component parts 130, 140 on the chips.

In the component 102 from FIG. 13, the contact structures 151, 153, 154 are also formed in a recessed manner in the insulating layer 160. As a result, it is possible to use a conversion element 140 having larger lateral dimensions than the silicone film 130 and to place it thereon in a planar manner.

A further possible modification of the component 102 from FIG. 13 consists of forming the contact structures 151, 153, 154 in a recessed manner only in the silicone film 130 and hence in the connection layer 131. With regard to the insulating layer 160, the contact structures 151, 153, 154 cannot be arranged in, but rather only on the layer 160. If the use of a conversion element 140 having larger lateral dimensions is provided here as well, planar bearing can be made possible by producing the layer 160 with a correspondingly smaller thickness.

A further possible modification appropriate for the components 102, 103 in FIGS. 13 and 16 consists, for example, of the layer 160 not completely surrounding the arrangement of chips 112. In this case, only partial sections of the layer 160 can be formed in the region of the contact structures to be produced at the edge of the chip arrangement.

Furthermore, attention is drawn to the possibility of carrying out formation of contact structures 151, 152, 153, 154 on the basis of other methods, rather than with the aid of an electroplating method. By way of example, the application or filling of a metal for the contact structures 151, 152, 153, 154 can be carried out with the aid of a conductive or metallic paste or with a solder material.

The above description mentions possible examples of the optoelectronic semiconductor chips 110, 111, 112 which have a carrier substrate and, arranged thereon, a useful layer or useful layer arrangement having a semiconductor layer sequence that emits light. In this case, the semiconductor chips 110, 111, 112 are arranged with the carrier substrates (or rear-side contacts or metallic layers arranged thereon) on the carrier 120 such that the useful layer is arranged on a side facing away from the carrier 120. Alternatively, however, other examples of light emitting semiconductor or thin-film chips can also be employed.

One possible example is so-called flip-chips in which a useful layer with a semiconductor layer sequence is arranged on a light-transmissive carrier substrate (in particular sapphire substrate). Such chips can be arranged with the useful layer or rear-side contacts arranged thereon on the carrier 120 such that the light-transmissive carrier substrate via which a light radiation can be emitted, is located on a side facing away from the carrier 120. Such a configuration in which a silicone film 130 is placed on the light-transmissive carrier substrate in the context of production may be appropriate for the semiconductor chips 111, for example.

The method described and its various examples are not just restricted to production of optoelectronic components in the form of white light sources, but can also be used to produce other light sources in which a light radiation having a different color is generated on the basis of the principle of additive light mixing. In this regard, the spectral ranges specified above for the semiconductor chips 110, 111, 112 and for the first and second phosphors can be replaced by other spectral ranges. On account of the accurately settable thickness of the connection layer 131 such components, too, can likewise be realized with a high color locus accuracy.

Furthermore, attention is drawn to the possibility of using, instead of a partly crosslinked bi-stage silicone film 130, some other film-type or continuous starting layer comprising a first phosphor which can be converted into a fixed connection layer 131 by curing or baking Such a starting layer can be formed from a partly crosslinked insulating material, in particular plastic or polymer material, which can be completely crosslinked by curing. Such a starting layer can likewise be provided in a frozen state and be obtained from a larger (frozen) film by cutting-out or stamping.

Furthermore, there is the possibility of using a different conversion element comprising a second phosphor instead of a ceramic conversion element 140 or a phosphor ceramic. One possible example is a conversion element formed from a polymer material or silicone and comprising the second phosphor. In this case, the second phosphor can likewise be present in the form of particles.

Although my components have been more specifically illustrated as described in detail by preferred or representative examples, nevertheless this disclosure is not restricted by those examples, and other variations can be derived therefrom by those skilled in the art, without departing from the scope of protection as defined in the appended claims.

1-17. (canceled)

18. A method of producing an optoelectronic component comprising:
providing at least one optoelectronic semiconductor chip;
arranging a starting layer on the semiconductor chip, wherein the starting layer is present in the form of a film and comprises a first phosphor, and the starting layer is arranged on the semiconductor chip in a frozen state as a film lamina;
arranging a ceramic conversion element on the starting layer, wherein the conversion element comprises a second phosphor; and
curing the starting layer to form a connection layer.

19. The method according to claim 18, wherein the film comprises a cut-out or stamped-out bi-stage silicone layer.

20. The method according to claim 18, wherein the starting layer is a partly crosslinked silicone film comprising the first phosphor, said silicone film being crosslinked during curing.

21. The method according to claim 18, wherein the semiconductor chip generates light radiation in the blue to ultraviolet spectral range.

22. The method according to claim 18, wherein the first phosphor converts part of the light radiation emitted by the semiconductor chip into light radiation in the red spectral range, and the second phosphor converts part of the light radiation emitted by the semiconductor chip into light radiation in the yellow to green spectral range.

23. The method according to claim 18, wherein curing the starting layer comprises carrying out a thermal process.

24. The method according to claim 18, wherein the semiconductor chip has a front-side contact, and the starting layer and the conversion element have a cutout for the front-side contact.

25. The method according to claim 18, wherein an arrangement comprising a plurality of optoelectronic semiconductor chips is provided, and the starting layer is arranged on the plurality of semiconductor chips.

26. The method according to claim 25, wherein the plurality of semiconductor chips have two front-side contacts, and contact structures are formed in the starting layer via which front-side contacts of semiconductor chips electrically connect to one another.

27. The method according to claim 26, wherein an insulating layer is formed, on which contact structures contacting the semiconductor chips are arranged.

28. The method according to claim 18, further comprising arranging the semiconductor chip or semiconductor chips on a carrier.

29. An optoelectronic component produced with the method according to claim 18, comprising: a carrier; a plurality of optoelectronic semiconductor chips arranged on the carrier in a matrix like manner or in a line; a single connection layer in form of a lamina, comprising a first phosphor, said connection layer being arranged on the semiconductor chips; and a single ceramic conversion element in form of a lamina, comprising a second phosphor, said conversion element being arranged on the connection layer, wherein the connection layer covers the plurality of semiconductor chips and is in total formed by curing a film-type starting layer comprising the first phosphor, wherein the starting layer and the conversion element are placed on top of each other in a planar manner and the conversion element has larger lateral dimensions than the starting layer, and wherein the starting layer does not project laterally beyond an edge of the semiconductor chips of the matrix arrangement or of the line arrangement.

30. The optoelectronic component according to claim 29, wherein the starting layer comprises a bi-stage silicone layer and traces of a material removal are formed at side surfaces of the bi-stage silicone layer.

31. The optoelectronic component according to claim 29, wherein the starting layer is a partly crosslinked silicone film comprising the first phosphor, and the connection layer is formed by crosslinking the silicone film.

32. The optoelectronic component according to claim 29, wherein the conversion element is a ceramic conversion element.

33. The optoelectronic component according to claim 29, wherein the semiconductor chips generate light radiation in the blue to ultraviolet spectral range, the first phosphor converts part of the light radiation emitted by the semiconductor chips into light radiation in the red spectral range, and the second phosphor converts part of the light radiation emitted by the semiconductor chips into light radiation in the yellow to green spectral range.

34. A method of producing an optoelectronic component comprising: providing at least one optoelectronic semiconductor chip; arranging a starting layer on the semiconductor chip, wherein the starting layer is present in the form of a film and comprises a first phosphor; arranging a conversion element on the starting layer, wherein the conversion element comprises a second phosphor; and curing the starting layer to form a connection layer.
